(19) United States
(12) Patent Application Publication
(10) Pub. No.: US 2021/0217609 A1
(43) Pub. Date: Jul. 15, 2021

(54) METHOD OR APPARATUS FOR FORMING THIN FILM ON SUBSTRATE EMPLOYING ATOMIC LAYER EPITAXY METHOD

(71) Applicant: TOKYO ELECTRON LIMITED, Tokyo (JP)

(72) Inventor: Munehito KAGAYA, Nirasaki City, Yamanashi (JP)

(21) Appl. No.: 17/058,975

(22) PCT Filed: May 27, 2019
(86) PCT No.: PCT/JP2019/020933

§ 371 Date: Nov. 25, 2020

(30) Foreign Application Priority Data
Jun. 6, 2018 (JP) 2018-108896

(51) Int. Cl. H01L 21/02; C23C 16/455; C23C 16/40; C23C 16/52; H01J 37/32

(52) U.S. Cl. CPC H01L 21/0228; H01L 21/02274; H01L 21/02211; H01L 21/02164; C23C 16/45536; H01J 2237/3321; C23C 16/401; C23C 16/45553; C23C 16/52; H01J 37/32449; C23C 16/45544

(57) ABSTRACT

[Problem] To provide a technique having high film thickness control performance in the formation of a thin film on a substrate. [Solution] A method for forming a thin film on a substrate employing atomic layer epitaxy method, comprising a step of supplying a precursor that is an aminosilane having one amino group onto the substrate, wherein the time for the supply of the precursor to be employed in the step is shorter than the time required for the adsorption amount of the precursor onto the substrate to be saturated. Because an aminosilane having one amino group is selected as the precursor and the time for the supply is shorter than the time required for the adsorption amount of the precursor to be saturated, it becomes possible to improve the film thickness control performance.

### TECHNICAL FIELD

The present disclosure relates to a method or an apparatus for forming a thin film on a substrate using atomic layer deposition.

### BACKGROUND

In a process of manufacturing a semiconductor device, as a method of forming a thin film on a semiconductor wafer (hereinafter, referred to as a “wafer”), which is a substrate, a process of forming a film through atomic layer deposition (hereinafter, also referred to as “ALD”) is known. As an example of a film forming apparatus that performs ALD using plasma, there is a film forming apparatus including a gas shower plate, which also serves as an upper electrode, and a stage, which also serves as a lower electrode, in a processing container.

In ALD performed using this film forming apparatus, first, a raw material gas is supplied into the processing container so that the raw material gas is adsorbed on the wafer. Next, a reaction gas is supplied into the processing container, and high-frequency power is applied between the electrodes to form plasma so as to activate the reaction gas, thereby causing the active species of the reaction gas and the raw material gas adsorbed on the wafer to react with each other. By repeating a plurality of cycles of alternately supplying the raw material gas and the reaction gas, it is possible to form a thin film having a desired film thickness. In this ALD process, it may be required to control a film thickness distribution in a wafer plane.

In Patent Document 1, a technique for forming a silicon nitride film or a silicon oxide film using alkylaminosilane is described. In this technique, a base material is irradiated with ammonia plasma or oxygen plasma, and then an alkylaminosilane is supplied. In this way, ammonia radicals or oxygen-containing radicals on the surface of the substrate are reacted with the alkylaminosilane, and thus a silicon nitride film or a silicon oxide film is formed. In addition, Patent Document 1 discloses an ALD saturation curve showing a relationship between a pulse supply time of an alkylaminosilane (here, diisopropylaminosilane (DIPAS)) and a deposition rate.

In Patent Document 2, a technique for improving uniformity in the composition of a third metal oxide film in a film thickness direction in forming the third metal oxide film containing a first metal element and a second metal element is described. In this technique, the metal oxide film containing the metal element present in the larger composition ratio between the first metal element and the second metal element is formed in a saturation mode, and the metal oxide film containing the metal element present in the smaller composition ratio is formed in an unsaturated mode.

### PRIOR ART DOCUMENTS

### Patent Documents

Patent Document 1: Japanese Laid-open Publication No. 2008-258591

Patent Document 2: Japanese Laid-open Publication No. 2011-18707

The present disclosure provides a technique having high controllability of a film thickness when forming a thin film on a substrate.

### SUMMARY

An aspect of the present disclosure is a method for forming a thin film using atomic layer deposition. The method includes a step of supplying a precursor, which is an aminosilane having one amino group, to the substrate. The supply time of the precursor in the above-mentioned step is shorter than the time required for the adsorbed amount of the precursor on the substrate to reach saturation.

According to the present disclosure, it is possible to improve the controllability of a film thickness when forming a film on a substrate.

### BRIEF DESCRIPTION OF DRAWINGS

FIG. 1 is a vertical cross-sectional view illustrating a configuration of a first embodiment of an apparatus according to the present disclosure.

FIG. 2 is a vertical cross-sectional view illustrating an exemplary configuration of a gas ejector provided in the apparatus.

FIG. 3 is a characteristic diagram showing an exemplary relationship between a partial pressure of a raw material gas ejected from the gas ejector and a position on a substrate.

FIG. 4 is a characteristic diagram showing an exemplary relationship between a dose amount of a raw material gas and a film formation rate.

FIG. 5 is a characteristic diagram showing an exemplary relationship between a dose amount of a raw material gas and a film formation rate.

FIG. 6A is a structural formula of an aminosilane having one amino group.

FIG. 6B is a structural formula of an aminosilane having two amino groups.

FIG. 6C is a structural formula of an aminosilane having three amino groups.

FIG. 7 is a chart showing an exemplary film forming method performed in the apparatus.

FIG. 8 is an explanatory view illustrating an exemplary gas supply state in the apparatus.

FIG. 9 is a vertical cross-sectional view illustrating an exemplary thin film formed by the apparatus.

FIG. 10 is a vertical cross-sectional view illustrating another exemplary thin film formed by the apparatus.

FIG. 11 is a vertical cross-sectional view illustrating a configuration of a second embodiment of the apparatus of the present disclosure.

FIG. 12 is a vertical cross-sectional view illustrating a configuration of a third embodiment of the apparatus of the present disclosure.

FIG. 13 is a characteristic diagram showing results of an evaluation test.

### DETAILED DESCRIPTION

### First Embodiment

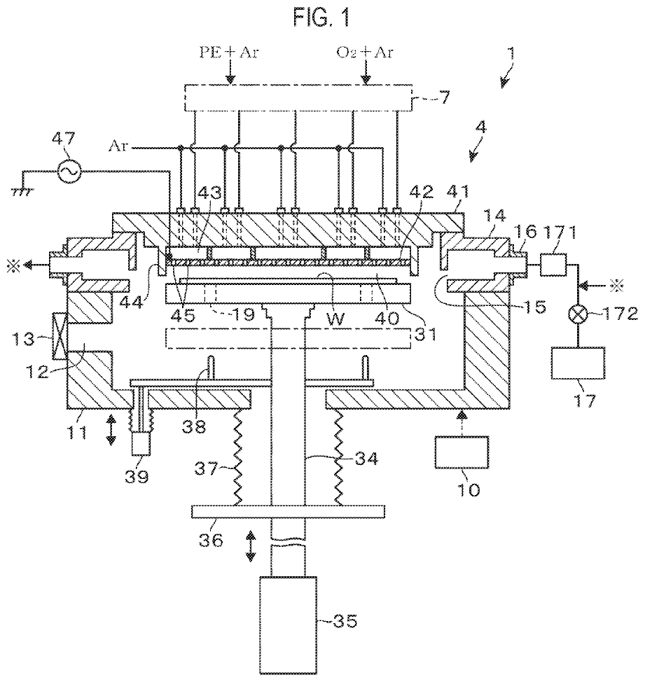

A film forming apparatus 1, which is an embodiment of an apparatus of the present disclosure, will be described with reference to the vertical cross-sectional view of FIG. 1. This film forming apparatus 1 is configured to alternately and repeatedly supply a raw-material gas and a reaction gas to a processing container 11, in which a wafer W is stored and processed, multiple times, and to form a thin film using atomic layer deposition (ALD). As the raw material gas, a gas containing a precursor, which is an aminosilane having one amino group, is used. Examples of this precursor may include diisopropylaminosilane (SiH₃N(CH(CH₃)₂)₂: DIPAS). In addition, as the reaction gas, an oxidation gas such as oxygen (O₂) gas or ozone (O₃) gas may be used.

(Processing Container)

The processing container 11 is formed in a substantially flat circular shape, and includes a wafer carry-in/out port 12 and a gate valve 13 for opening and closing the carry-in/out port 12, which are installed in the side wall thereof. An exhaust duct 14 forming a portion of the side wall of the processing container 11 is installed on the upper side of the carry-in/out port 12. A slit-shaped opening 15 extending along the circumferential direction is formed in the inner peripheral surface of the exhaust duct 14, and forms an exhaust port of the processing container 11. One end of an exhaust pipe 16 is connected to the exhaust duct 14, and the other end of the exhaust pipe 16 is connected to the exhaust mechanism 17 including a vacuum pump via a pressure adjustment mechanism 171 and a valve 172.

(Placement Part)

A disc-shaped placement part 31 on which the wafer W is horizontally placed is installed in the processing container 11. A heater for heating the wafer W and a grounded electrode plate are embedded in the placement part 31. The heater and the electrode plate are not illustrated.

The upper end of a support member 34, which extends in the vertical direction through the bottom portion of the processing container 11, is connected to the central portion of the bottom side of the placement part 31, and the lower end of the support member 34 is connected to a lifting mechanism 35. By this lifting mechanism 35, the placement part 31 can be raised and lowered between the lower position indicated by a chain line in FIG. 1 and the upper position indicated by a solid line in FIG. 1. The lower position is a delivery position for delivering a wafer W to and from a transport mechanism (not illustrated) of the wafer W entering the processing container 11 from the carry-in/out port 12. In addition, the upper position is a processing position at which a film forming process is performed on the wafer W.

Reference numeral 36 in FIG. 1 denotes a flange, and reference numeral 37 denotes a stretchable bellows. In addition, reference numeral 38 in the drawing denotes support pins for the wafer W. For example, three support pins are provided (only two are illustrated in the drawing). Further, reference numeral 39 in FIG. 1 denotes a lifting mechanism for raising and lowering the support pins 38. When the support pins 38 are raised and lowered through the through holes 19 formed in the placement part 31 when the placement part 31 is positioned at the delivery position, the support pins 38 protrude and retreat from the top surface of the placement part 31. By this operation, the wafer W can be delivered between the placement part 31 and the transport mechanism.

(Gas Ejector)

On the upper side of the exhaust duct 14, a gas ejector 4 is installed so as to face a wafer W placed on the placement part 31. The gas ejector 4 in this example includes a ceiling plate member 41 installed so as to close the inside of the processing container 11 from the top side of the processing container 11, and a shower plate 42 installed on the bottom side of the ceiling plate member 41. The shower plate 42 is formed in a disc shape and is arranged so as to face the placement part 31.

A flat circular gas diffusion space 43 is formed between the ceiling plate member 41 and the shower plate 42. A plurality of gas ejection holes 45, which opens toward the gas diffusion space 43, is formed in a distributed arrangement in the shower plate 42. In this example, the peripheral edge of the shower plate 42 is supported by an annular protrusion 44 protruding downward from the bottom surface of the ceiling plate member 41. The lower end portion of the annular protrusion 44 protrudes to a position close to the top surface on the peripheral edge side of the placement part 31 arranged at the processing position.

(Partitioned Region)

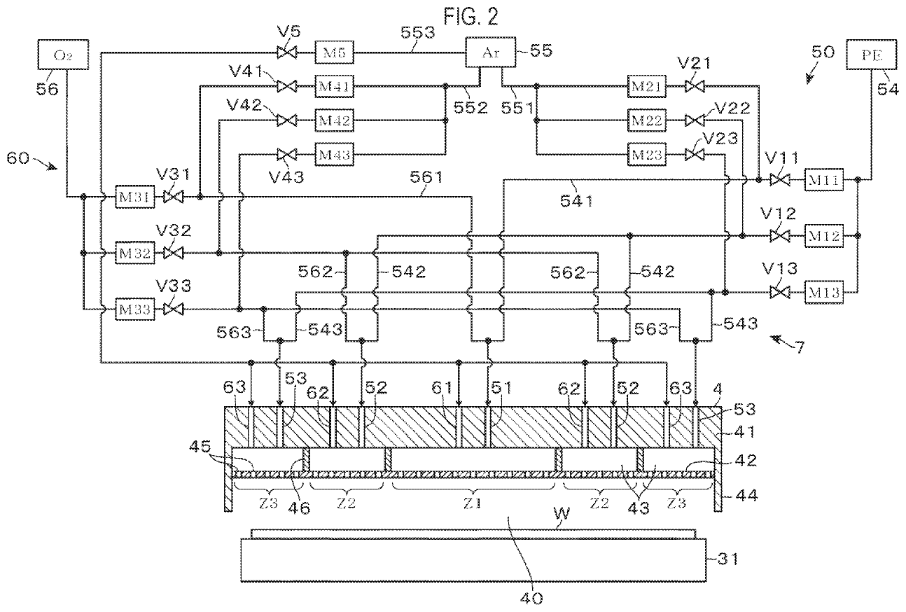

In the gas ejector 4, a plurality of partitioned regions is formed by concentrically partitioning the region in which the gas ejection holes 45 are arranged into multiple regions corresponding to the radial direction of the wafer W, and is also configured to be capable of ejecting gas independently of each other. More specifically, as illustrated in FIG. 2, the gas diffusion space 43 is partitioned into multiple portions in concentric circular shapes by partition walls 46 corresponding to the radial direction of the wafer W placed on the placement part 31. That is, when viewed from the placement part 31 side, the arrangement region of the plurality of gas ejection holes 45 in the shower plate 42 is divided into three partitioned regions (a first partitioned region Z1, a second partitioned region Z2, and a third partitioned region Z3) in the radial direction.

In the following description, the partitioned regions of the gas diffusion space 43 in the gas ejector 4 will also be referred to as first to third partitioned regions Z1 to Z3. These first to third partitioned regions Z1 to Z3 divide the shower plate 42, which is circular in a plan view, in concentric circular shapes, and the first partitioned region Z1 has a circular shape with each of the second and third partitioned regions Z2 and Z3 having a ring shape. The gas diffusion space 43 is not limited to being partitioned into completely concentric circular shapes, and these partitioned areas Z1 to Z3 may be formed by partitioning the gas diffusion space 43 into concentric elliptical or rectangular shapes.

(Gas Supplier)

The gas ejector 4 is installed with a precursor supplier 50 configured to supply a precursor as a raw-material gas, and a reaction gas supplier 60 configured to supply O₂ gas as a reaction gas. From the precursor supplier 50 and the reaction gas supplier 60, the precursor and the reaction gas are supplied to each of the partitioned regions Z1 to Z3 independently of each other. In this example, processing gas supply paths 51, 52, and 53 are formed in the ceiling plate member 41 of the gas ejector 4 so as to supply the precursor and the reaction gas to the partitioned regions Z1 to Z3, respectively. In the ceiling plate member 41, purge gas supply paths 61, 62, and 63 are formed so as to supply a purge gas to the partitioned region Z1 to Z3, respectively.

The number of processing gas supply paths 51, 52, and 53 and purge gas supply paths 61, 62, 63 illustrated in FIGS. 1 and 2 is an example. In practice, the first to third partitioned regions Z1 to Z3 are appropriately provided with the required number of processing gas supply paths 51, 52, and 53 and purge gas supply paths 61, 62, and 63.

A raw material gas, a reaction gas, and a carrier gas are supplied to these processing gas supply paths 51, 52, and 53, respectively, via a supply control device 7. As illustrated in FIG. 2, the supply control device 7 includes, for example, a supply path for a precursor, a reaction gas, or a carrier gas, a valve, and a flow rate adjustment part including a mass flow controller.

The processing gas supply paths 51, 52, and 53 are connected to a supply source 54 of a precursor (referred to as “PE (Precursor of Example)” in FIGS. 1 and 2) via the precursor supply paths 541, 542, and 543, respectively. Valves V11, V12, and V13 for precursor supply operation and flow rate adjustment parts M11, M12, and M13 are installed in the precursor supply paths 541, 542, and 543, respectively. In addition, the processing gas supply paths 51, 52, and 53 are also connected to the supply source 55 of Ar gas, which is a carrier gas, via the precursor supply paths 541, 542, and 543, respectively, and the carrier gas supply path 551. Valves V21, V22, and V23 for supplying a carrier gas and flow rate adjustment parts M21, M22, and M23 are installed in the carrier gas supply path 551.

In addition to the supply sources 54 and 55, the processing gas supply paths 51, 52, and 53 are connected to the supply source 56 of the reaction gas (O₂ gas) via the reaction gas supply paths 561, 562, and 563, respectively. Valves V31, V32, and V33 for reaction gas supply operation and flow rate adjustment parts M31, M32, and M33 are installed in the reaction gas supply paths 561, 562, and 563, respectively. In addition, the processing gas supply paths 51, 52, and 53 are also connected to the supply source 55 of the carrier gas via the reaction gas supply paths 561, 562, and 563, respectively, and the carrier gas supply path 552. Valves V41, V42, and V43 for supplying a carrier gas and flow rate adjustment parts M41, M42, and M43 are installed in the carrier gas supply path 552.

In this example, the precursor supplier 50 includes the processing gas supply paths 51, 52, and 53, the precursor supply paths 541, 542, and 543, the valves V11, V12, and V13, the flow rate adjustment parts M11, M12, and M13, and the supply source 54 of the precursor. In addition, the reaction gas supplier 60 includes the processing gas supply paths 51, 52, and 53, the reaction gas supply paths 561, 562, and 563, the valves V31, V32, and V33, the flow rate adjustment parts M31, M32, and M33, and the supply source 56 of the reaction gas.

The purge gas supply paths 61, 62, and 63 merge with, for example, the supply path 553 in the middle thereof, and each of the purge gas supply paths 61, 62, and 63 is connected to the supply source 55 of the Ar gas (which is a purge gas) via the valve V5 and the mass flow controller M5. The operations of each valve and each flow rate adjustment part are controlled by the controller 10 to be described later.

In the supply control device 7 including the configuration described above, when the precursor is supplied to the wafer W, the valves V11, V12, and V13 for supplying the precursor are opened. When supplying the reaction gas to the wafer W, the valves V31, V32, and V33 for supplying the reaction gas are opened. When supplying the carrier gas to the wafer W, the valves V21, V22, and V23 or the valves V41, V42, and V43 for supplying Ar gas are opened.

As a result, the precursor or reaction gas diluted with a predetermined amount of carrier gas is supplied to the first to third partitioned regions Z1 to Z3 of the gas diffusion space 43 through the precursor supply paths 541 to 543 and the processing gas supply paths 51 to 53, respectively. In addition, the precursor or the reaction gas is ejected into the processing space 40 from the gas ejection holes 45 formed in each of the partitioned regions Z1 to Z3 of the shower plate 42.

The precursor or reaction gas ejected from the partitioned regions Z1 to Z3 is supplied to adsorption regions of the wafer W facing the partitioned regions Z1 to Z3 of the shower plate 42. That is, a plurality of adsorption regions concentrically partitioned in the radial direction is formed in the regions of the wafer W that face the respective partitioned regions Z1 to Z3.

Therefore, when the ejection flow rate of the precursor per unit area is set to be different among the first to third partitioned regions Z1 to Z3 on the gas ejector 4 side, the flow rate (supply flow rates) of the precursor supplied per unit area will be different among the three adsorption regions on the wafer W side. In addition, when the ejection time of the precursor is set to be different among the first to third partitioned regions Z1 to Z3 on the gas ejector 4 side, the supply time of the precursor will be different among the three adsorption regions on the wafer W side.

(Processing Space and Plasma Generation Mechanism)

Returning to FIG. 1, the description is continued. The space surrounded by the bottom surface of the shower plate 42, the annular protrusion 44, and the top surface of the placement part 31 forms the processing space 40 in which the above-mentioned film forming process is performed. The shower plate 42 is paired with an electrode plate (not illustrated) of the placement part 31, and is configured as an electrode plate for forming capacitively coupled plasma (CCP) in the processing space 40. A high-frequency power supply 47 is connected to the shower plate 42 via a matcher (not illustrated). The above-mentioned CCP is formed by supplying high-frequency power from a high-frequency power source 47 to the gas supplied to the processing space 40 through the shower plate 42. The shower plate 42, the electrode plate, and the high-frequency power supply 47 form a plasma generation mechanism. Instead of the shower plate 42, the high-frequency power supply 47 may be connected to the electrode plate on the placement part 31 side so as to ground the shower plate 42.

(Controller)

The film forming apparatus 1 is provided with a controller 10 configured with a computer. The controller 10 includes, for example, a data-processing part including programs, a memory, and a CPU. The programs incorporate instructions such that a control signal can be sent from the controller 10 to each part of the film forming apparatus 1 so as to execute a film forming process to be described later. Specifically, for example, the timing of opening/closing each valve, the timing of turning on/off the high-frequency power supply 47, and the heating temperature of the wafer W by the heater are controlled by the above-mentioned programs. These programs are stored in a storage medium such as a compact disc, a hard disc, or an MO (Magneto-Optical Disc), and are installed in the controller 10.

Further, the controller 10 is configured to output a control signal for adjusting the ejection time of the precursor from the gas ejector 4 to be shorter than the time required for the adsorbed amount of the precursor on the wafer W to reach saturation. The controller 10 is configured to output a control signal that makes at least one of the ejection flow rate of the precursor per unit area and the ejection time different between at least two partitioned regions among the plurality of partitioned regions Z1 to Z3 of the gas ejector 4. Further, when the reaction gas (O₂ gas) is ejected from the gas ejector 4, the controller 10 is configured to output a control signal to the plasma generator so as to plasmarize the O₂ gas.

The present disclosure enhances the controllability of a film thickness by setting, in the step of supplying a precursor which is an aminosilane having one amino group, the supply time of the precursor to be shorter than the time for the adsorbed amount of the precursor on the wafer W to reach saturation (hereinafter, also referred to as the “saturated adsorption time”). Hereinafter, an outline of the present disclosure will be described.

(Formation of Silicon Oxide Film by ALD)

First, a reaction mechanism presumed to be proceeding on the surface of the wafer W, which is a silicon substrate, in the process of forming a silicon oxide film on the wafer W by ALD will be briefly described. A silicon substrate is a substrate containing, on the surface thereof (the surface on which the precursor is adsorbed), silicon (Si) terminated with a hydroxy group (OH group). When the precursor, aminosilane, is supplied, the amino group of an aminosilane (an NH₂ group, a primary amino group (NHR1 group), or a secondary amino group (NR1R2 group), in which R1 and R2 in the explanation in this paragraph are substituents other than hydrogen) and the hydrogen (H) of a hydroxy group are bonded and eliminated. Meanwhile, oxygen (O) on the surface of the wafer W and silicon (Si) of the precursor are bonded, and the precursor is adsorbed. Next, when O₂ gas, which is a reaction gas, is supplied and plasmarized, the precursor adsorbed on the wafer W is oxidized by the active species of O₂ generated by the plasma, and one molecular layer of a silicon oxide film (SiO) is formed. By alternately and repeatedly supplying the precursor and the reaction gas multiple times, a SiO thin film (SiO film) having a target film thickness is formed. In addition to using O₃ gas as the reaction gas, plasma may be generated to oxidize the precursor.

(Relationship Between Partial Pressure of Precursor and in-Plane Distribution of Film Thickness)

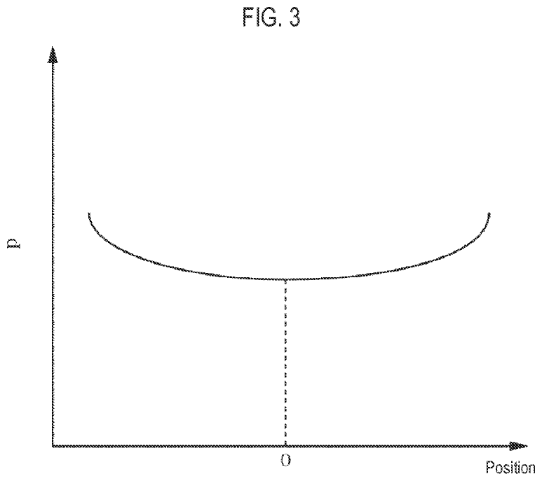

FIG. 3 is a characteristic diagram schematically showing a relationship between a radial position of a wafer W and the partial pressure of a precursor. In FIG. 3, the horizontal axis represents a radial position of the wafer W in the radial direction, the vertical axis represents the partial pressure “p” of a precursor, and “O” of the horizontal axis represents the center of the wafer W. When Ar, which is a purge gas, is constantly supplied, and a raw material gas, which is a mixture gas of a precursor, a carrier gas, and a purge gas, is supplied from the entire surface of the shower plate 42 at a constant total pressure, the partial pressure corresponds to the concentration of the precursor in the raw material gas. In this case, it is possible to change the partial pressure of the precursor by adjusting the mixing ratio of the precursor and the carrier gas in the raw material gas.

In ALD, the adsorbed amount of the precursor is reflected in the film thickness. Therefore, as shown in FIG. 3, when the precursor is supplied such that the partial pressure of the precursor becomes larger on the peripheral edge side than in the central portion of the wafer in the radial direction of the wafer W, the adsorbed amount of the precursor also changes according to the partial pressure. As a result, under the condition that the supply time of the raw material gas is the same, the thickness of the SiO film seen along the radial direction of the wafer W is larger in the peripheral edge portion than in the central portion. However, in the present disclosure, it has been found that when a saturated amount of precursor is adsorbed on the wafer W, it becomes difficult to significantly change the film thickness distribution even if the partial pressure of the precursor and the supply time are changed, and thus the controllability is deteriorated in some cases.

(Saturation of Adsorbed Amount of Precursor)

Therefore, in the present disclosure, the supply time of the precursor is controlled to be shorter than the time required for the adsorbed amount of the precursor on the wafer W to reach saturation. The term “saturation” as used herein means the maximum amount of the precursor that can be adsorbed on the adsorption site on the surface of the wafer W. In the example of the silicon substrate described above, the aminosilane is adsorbed by reacting with the hydroxy group (OH group) on the surface of the silicon substrate, and thus the hydroxy group becomes the adsorption site.

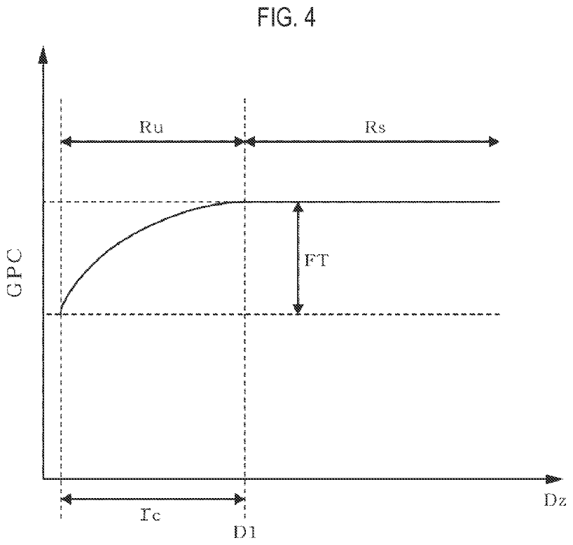

The concept of controllability of a film thickness will be described with reference to FIG. 4. FIG. 4 schematically shows a relationship between a dose amount of a precursor in one cycle and a film formation rate per cycle. In FIG. 4, the horizontal axis “Dz” represents a dose amount, and the vertical axis “GPC” represents a film formation rate (Å/cycle). Here, the dose amount is the supply amount of a precursor per unit area (mg/cm²). The dose amount is adjusted depending on the supply flow rate of the precursor contained in the raw material gas (=the supply flow rate of the raw material gas×the partial pressure ratio of the precursor in the raw material gas) and the supply time. For example, when the supply flow rate is constant, increasing the supply time increases the dose amount, and when the supply time is constant, increasing the supply flow rate increases the dose amount.

As shown in FIG. 4, the film formation rate increases as the dose amount increases, but when the dose amount exceeds a certain amount D1, the film formation rate becomes almost constant. At this time, it is considered that a saturated amount of precursor is adsorbed on the surface of the wafer W. Therefore, in the region where the dose amount is D1 or more, the film thickness does not change even if the dose amount is increased. Therefore, in order to control the film thickness by adjusting the dose amount of the precursor, it is necessary to adjust the dose amount in a region where the dose amount is smaller than D1.

As can be seen from the illustration of FIG. 4, the “saturated” state can be experimentally confirmed from the state in which the film formation rate does not increase any further even if the dose amount of the precursor in one cycle is increased.

From the above, in the present disclosure, the controllability of the film thickness can be ensured by adjusting the supply time of the precursor to be shorter than the saturated adsorption time. However, in the correspondence relationship between the actual dose amount and the GPC, the film formation rate may not be completely constant, and the GPC may continue to increase slightly with the increase in the dose amount. Therefore, based on the evaluation test to be described later, the time during which the amount of increase in film formation rate (GPC) becomes 0.05 Å/sec when the supply flow rate of the precursor is maintained constant and the supply time is increased by a unit time may be regarded as a substantial “saturated adsorption time,” and the slight increase in GPC may be ignored.

Next, the concept of controllability of a film thickness will be described. In FIG. 4, “Rs” indicates a saturated region, and “Ru” indicates an unsaturated region. As described above, in the present disclosure, the film thickness is controlled in the region where the dose amount belongs to the unsaturated region Ru. Therefore, when the dose amount is changed within the range indicated by “rc” in FIG. 4, the film thickness corresponding to each dose amount is obtained. Therefore, as the control range of the film thickness that can be adjusted within the adjustment range rc of the dose amount (hereinafter, also referred to as a “film thickness range FT”), the controllability of the film thickness adjustment is improved. Therefore, in the present disclosure, as an index for determining the ease of film thickness control, it is evaluated that the larger the film thickness range FT, the better the film thickness controllability. As shown in FIG. 4, based on the minimum value (Min) and the maximum value (Max) of a film thickness, the film thickness range FT may be determined by FT=Max−Min.

(Precursor)

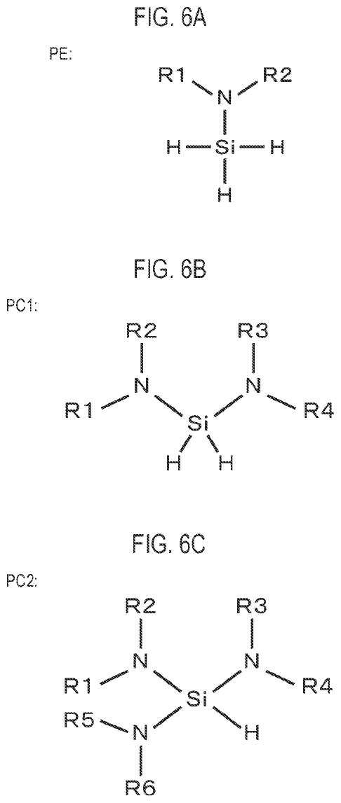

The present disclosure has a technical point in that an aminosilane having one amino group is selected as a precursor having good controllability. The aminosilane having one amino group is an aminosilane having only one amino group, and does not include an aminosilane having two or more amino groups. Specifically, as shown in the structural formula of FIG. 6A, it is represented by SiH₃NR1R2. As “R1” and “R2,” hydrogen groups, saturated chain hydrocarbon groups, unsaturated chain hydrocarbon groups, saturated ring hydrocarbon groups, aromatic hydrocarbon groups, halogen groups, hydroxy groups, carboxyl groups, ester groups, and acyl groups may be exemplified.

Specifically, the aminosilane having one amino group may be exemplified by SiH₃NH₂, SiH₃(N(CH₃)₂), SiH₃(NH(CH₃)), SiH₃(N(CH₂CH₃)₂), SiH₃(NCH₃(CH₂CH₃)), SiH₃(NH(CH₂CH₃)), SiH₃(N(CH₂CH₂CH₃)₂), SiH₃(NH(CH₂CH₂CH₃)), SiH₃(NHCH(CH₃)₂), SiH₃(N(C(CH₃)₃)₂), or SiH₃(NHC(CH₃)₃). The number of silicon atoms contained in the aminosilane having one amino group is not limited to one, and an aminodisilane such as diisopropylaminosilane (SiH₃SiH₂(N(CH(CH₃)₂)₂)): DIPADS) or aminotrisilane may also be used.

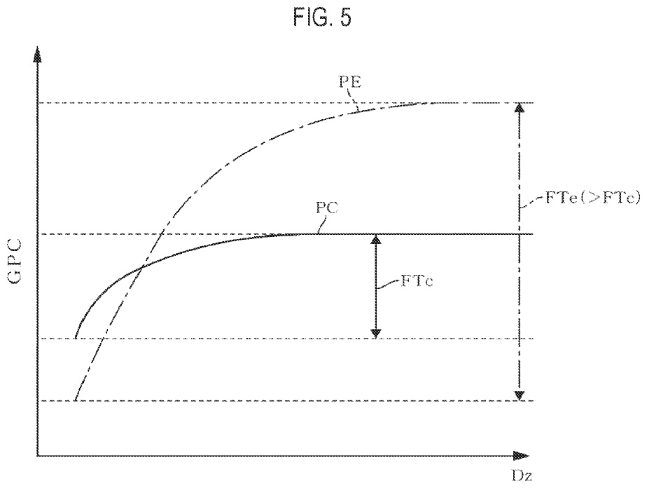

FIG. 5 schematically shows a difference in controllability between different precursors. In FIG. 5, the horizontal axis “Dz” represents a dose amount, the vertical axis “GPC” represents a film formation rate (Å/cycle), “PE” in the figure represents the precursor of the example, and “PC” (Precursor of Comparative) represents the precursor of a comparative example. The precursor of the example is an aminosilane having one amino group, and the precursor of the comparative example is an aminosilane having two or three amino groups. The aminosilane having two amino groups here means an aminosilane having only two amino groups, and the aminosilane having three amino groups means an aminosilane having only three amino groups.

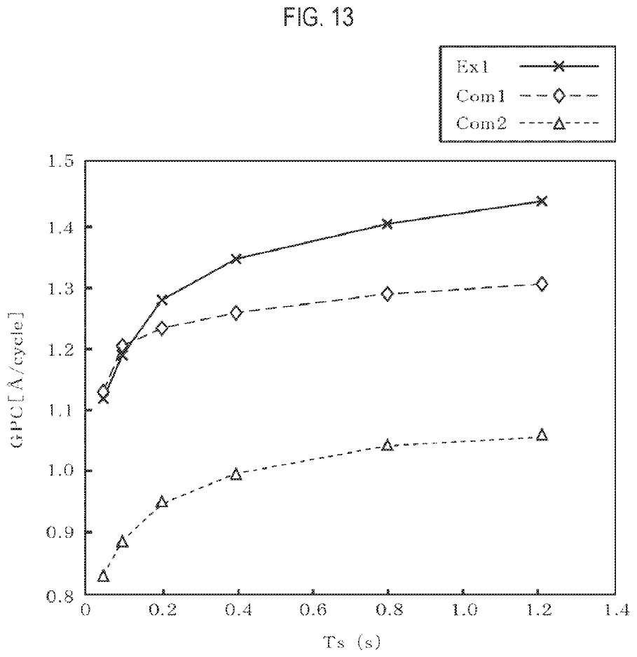

In the present disclosure, as shown in FIG. 5, it has been found that the shape of the curve showing an increase in a film formation rate with respect to an increase in a dose amount differs greatly depending on the type of a precursor (see the test results shown in FIG. 13 as well). The shape of the curve represents the controllability of a film thickness, and the larger the film thickness range FT and the steeper the curve in the unsaturated region, the higher the controllability of the film thickness. In FIG. 5, the film thickness range FTe of Example PE is larger than the film thickness range FTc of Comparative Example PC, and the curve in the unsaturated region is steep. Therefore, it is understood that by using the precursor of Example PE, the controllability of the film thickness is enhanced.

The reason that the controllability of the film thickness is enhanced by selecting an aminosilane having one amino group as a precursor compared with the case where an aminosilane having two or more amino groups is used is considered to be as follows. FIG. 6B shows a structural formula of an aminosilane having two amino groups, and FIG. 6C shows a structural formula of an aminosilane having three amino groups.

In the step of causing the precursor to be adsorbed on the wafer W in ALD, since the precursor having multiple amino groups has many amino groups, even if an adsorption site on which the precursor can be adsorbed remains, the precursor may tend to be in the state in which the precursor cannot be adsorbed due to steric hindrance. In contrast, it is presumed that the aminosilane having one amino group has relatively less steric hindrance compared with the precursor having multiple amino groups, and that the adsorbed amount at the time of saturation due to the reaction with the hydroxy groups on the wafer surface is large. As described above, the fact that the adsorbed amount at the time of saturation is large means that the adjustment range of the adsorbed amount at the time of non-saturation is large, and it is suggested that the adjustment range of the film thickness is large and the controllability is high.

(Film Forming Method Conducted in Film Forming Apparatus)

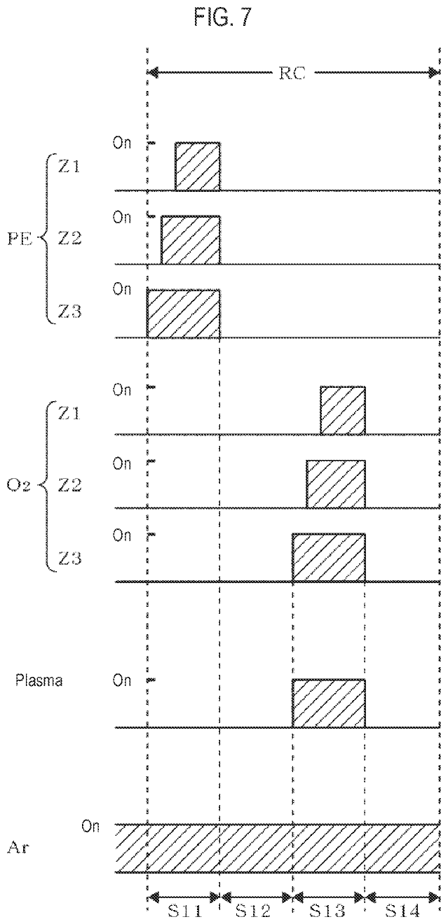

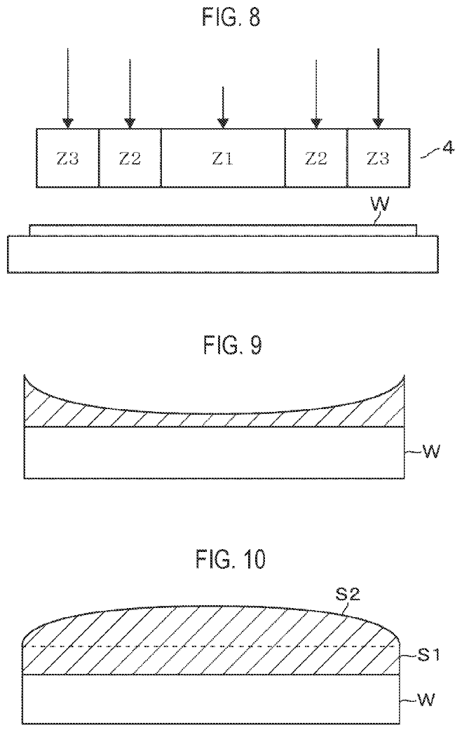

Subsequently, an exemplary film forming method according to the present disclosure conducted in the film forming apparatus 1 will be described with reference to FIGS. 7 and 8. In the film forming method of this embodiment, the process is performed under the condition in which a film thickness distribution in which the film thickness in the peripheral edge portion of a wafer is larger than that in the central portion of the wafer is formed. The chart of FIG. 7 shows the timing of starting and stopping the supply of various gases into the processing container 11 and the timing of turning on/off the high-frequency power supply 47 (plasma).

First, the gate valve 13 is opened in the state in which the inside of the processing container 11 has a predetermined vacuum atmosphere, and a wafer W is transported from a transport chamber, which is located adjacent to the processing container 11 and having a vacuum atmosphere, onto the placement part 31 located at the delivery position by a transport mechanism. When the wafer W is delivered to the placement part 31 by raising and lowering the support pins 38 and the transport mechanism is unloaded from the processing container 11, the gate valve 13 is closed and the placement part 31 is raised to the processing position, forming the processing space 40. Further, the wafer W is heated to a predetermined temperature by the heater of the placement part 31.

Next, the valves V21 to V23 and V41 to V43 are opened, and Ar gas is supplied to the processing space 40 from the supply source 55. Subsequently, the valves V11 to V13 are opened, and the precursor, DIPAS, is ejected from the supply source 54 to the processing space 40 through the gas ejection holes 45 in the first to third partitioned regions Z1 to Z3. In this way, the precursor is supplied to the wafer W, and the precursor is adsorbed on the surface of the wafer W (step S11).

The supply time of the precursor to the wafer W in one cycle RC at this time is shorter than the saturated adsorption time described above. As shown in FIGS. 7 and 8, when the supply flow rates of the raw material gases (precursor and Ar gas) are the same, the gas ejector 4 is supplied with the precursor such that the supply time to the first partitioned region Z1 is the shortest and the supply time becomes longer toward the third partitioned region Z3 of the peripheral edge portion. As a result, when viewed from the wafer W side, the supply time of the precursor to the adsorption region facing the first partitioned region Z1 is the shortest, and the supply time becomes longer toward the adsorption region facing the second partitioned region Z2 and the adsorption region facing the third partitioned region Z3. FIG. 8 schematically shows that in the partitioned regions Z1 to Z3, the supply time is longer in a partitioned region indicated by a longer arrow, and the dose amount of the precursor is increased in the adsorption region facing the partitioned region.

Subsequently, the valves V11 to V13 are closed to stop the supply of the precursor to the wafer W. By continuing the supply of Ar gas, the precursor remaining in the processing space 40 and not adsorbed on the wafer W is purged with the Ar gas (step S12). In this way, the precursor supplier 50 supplies a mixture gas of Ar gas, which is a carrier gas, and the precursor during a time period of supplying the precursor, and continues the supply of Ar gas during a time period other than the time period of supplying the precursor. As a result, backflow of the precursor and the reaction gas to the processing gas supply paths 51 to 53, the precursor supply paths 541 to 543, and the reaction gas supply paths 561 to 563 is prevented.

Next, the valves V31 to V33 are opened, the reaction gas is ejected from the supply source 56 of the reaction gas to the processing space 40 from the gas ejection holes 45 in the first to third partitioned regions Z1 to Z3, and the high-frequency power supply 47 is turned on. As shown in FIG. 7, for example, when the supply flow rates of the reaction gas and Ar gas are the same, the supply time of the reaction gas in this case is controlled such that the supply time to the first partitioned region Z1 is the shortest, and the supply time becomes longer toward the third partitioned region Z3. In this way, O₂ gas, which is the reaction gas in the processing space 40, is plasmarized, and the precursor adsorbed on the wafer W is oxidized by the plasma to form a SiO layer as a reaction product (step S13).

Thereafter, the formation of plasma and the supply of reaction gas in the processing space 40 are stopped by turning off the high-frequency power supply 47 and closing the valves V31 to V33. By continuing the supply of Ar gas, the reaction gas remaining in the processing space 40 and the active species of the deactivated plasma are purged with the Ar gas and removed from the processing space 40 (step S14). In this way, the reaction gas supplier 60 is configured to supply a mixture gas of Ar gas, which is a carrier gas, and the reaction gas during a time period of supplying the reaction gas, and to continue the supply of Ar gas during a time period other than the time period of supplying the reaction gas. As a result, backflow of the precursor and the reaction gas to the processing gas supply paths 51 to 53, the precursor supply paths 541 to 543, and the reaction gas supply paths 561 to 563 is prevented.

Next, the valves V11 to V13 are opened again, the precursor is supplied to the wafer W as described above, and the above step S11 is performed. One cycle RC of film formation is executed by a series of steps S11 to S14, and this cycle RC is repeated a set number of times, thereby laminating a layer of SiO on the surface of the wafer W so as to form a SiO film having a predetermined film thickness. When steps S11 to S14 are repeated the set number of times, the placement part 31 is lowered, and the wafer W is carried out from the processing container 11 in the reverse of the procedure for carrying the wafer W into the processing container 11, whereby the film forming process is finished.

The above-described method for forming a SiO film through ALD is an example, and a step of flowing non-plasmarized O₂ gas may be inserted between steps S12 and S13. In this case, one film forming cycle is performed by supply of a precursor→continuous supply of purge gas→supply of O₂ gas→supply of O₂ gas and generation of SiO by generation of plasma→continuous supply of purge gas.

In addition, O₂ gas, which is a reaction gas, may be constantly supplied during the film forming process. In this case, O₂ gas and purge gas are continuously supplied, and one film forming cycle is performed by supply of precursor→continuous supply of O₂ gas and purge gas→generation of SiO by plasma generation→continuous supply of O₂ gas and purge gas. In this example, when the precursor is supplied, a mixture gas of the precursor, the carrier gas, the purge gas, and the O₂ gas becomes the raw material gas. Therefore, the partial pressure of the precursor in the raw material gas can be adjusted depending on the mixing ratio of the precursor, the carrier gas, and the O₂ gas.

### Effect of Embodiment

In the embodiment described above, an aminosilane having one amino group is selected as the precursor, and the supply time of the precursor allocated in one cycle is set to be shorter than the time required for the adsorbed amount of the precursor on the wafer W to reach saturation (saturated adsorption time). Therefore, as described above, it is possible to enhance the controllability of a film thickness by maintaining the change in film thickness with respect to the change in the dose amount to be large.

In the step of supplying the precursor, the supply time of the precursor is set to be different between at least two adsorption regions among the plurality of adsorption regions of the wafer W. In this way, as shown in FIG. 8, the supply time of the precursor and the reaction gas is controlled such that the supply time is the shortest in the central portion of the wafer W and becomes longer toward the peripheral edge portion. As a result, as shown in FIG. 9, it is possible to form, in the wafer plane, a SiO film having a film thickness distribution in which the film thickness in the peripheral edge portion is larger than that in the central portion. In this way, by changing the supply time of the precursor to the adsorption region of the wafer W, the amount of the precursor supplied to the wafer W changes. This may make the film thickness large in the region where the supply time is long and make the film thickness small in the region where the supply time is short, so that it is possible to control the film thickness distribution.

Further, in the step of supplying the precursor, when the supply time is the same between at least two adsorption regions among multiple adsorption regions of the wafer W, the film thickness distribution may be controlled by making the supply flow rate of the precursor per unit area different between the at least two adsorption regions. When the ejection time of the gas ejected from each of the partitioned regions Z1 to Z3 is the same, this supply flow rate can be adjusted by changing the partial pressure (concentration) of the precursor in the gas. As a result, on the wafer W side, the mass flow rate of the precursor per unit area [mg/cm²·sec] is adjusted.

Further, in the gas ejector 4 in the above-described embodiment, multiple partitioned regions are formed by concentrically partitioning the region in which the gas ejection holes 45 are arranged into multiple regions corresponding to the radial direction of the wafer W. The multiple partitioned regions are capable of ejecting gas independently of each other. Therefore, since the precursor can be individually supplied to each partitioned region, it is possible to independently control the ejection flow rate and ejection time of the precursor for each partitioned region. As a result, since it is possible to change the supply flow rate and supply time of the precursor in the plane of the wafer W, it is easy to control the film thickness distribution of the thin film.

(Another Example of Thin Film)

Subsequently, another example of controlling the film thickness distribution of a thin film formed by the method of the present embodiment will be described with reference to FIG. 10. The thin film of this example is a laminate of a flat film 51 on the wafer W, and a film S2 having, for example, a film thickness distribution in the plane of the wafer W in which the film thickness in the central portion is larger than that in the peripheral portion. In this example, first, the film 51 having a flat film thickness distribution is formed on the wafer W by ALD (a first film forming process), and then the film S2 having a film thickness distribution that includes a high central portion is formed by ALD (a second film forming process). In the first and second film forming processes as well, a SiO film having a predetermined film thickness is formed by repeating, a set number of times, a film forming cycle consisting of supply of a precursor→purging→supply of a reaction gas→purging in the film forming apparatus 1 described above.

In this example, for example, in the second film forming process, the reaction gas is supplied such that the supply time of the reaction gas is shorter than the saturated adsorption time. In the first film forming process, the precursor is supplied to the plurality of adsorption regions of the wafer W such that the supply flow rates in the plurality of adsorption regions are equal to one another, and the supply times of the precursor per unit area of the plurality of adsorption regions are equal to one another. For example, even in the reaction gas supply step, the reaction gas is supplied to the plurality of adsorption regions of the wafer W such that the supply flow rates of the plurality of adsorption regions are equal to one another, and the supply times of the reaction gas per unit area of the plurality of adsorption regions are equal to one another. This causes SiO to be uniformly deposited in the plane of the wafer W, and thus a flat SiO film is formed.

In the second film forming process, in the precursor supply step, the precursor is supplied such that at least one of the supply flow rate and the supply time of the precursor per unit area are different for the plurality of adsorption regions of the wafer W. For example, in the case of changing the supply flow rate, when the supply time of the precursor is the same, the ejection flow rate from the first partitioned region Z1 becomes the greatest, and the ejection flow rate from the third partitioned region Z3 becomes the smallest. For example, in the case of changing the supply time, when the supply flow rate of the precursor is the same, the ejection time from the first partitioned region Z1 becomes the longest, and the ejection time from the third partitioned region Z3 becomes the shortest.

In the reaction gas supply step, for example, the reaction gas is supplied such that the supply flow rates and the supply time per unit areas are different from each other for the plurality of adsorption regions of the wafer W, like the precursor. As shown in FIG. 10, in the SiO film formed in this way, the flat SiO film S1 is formed on the wafer W, and the SiO film S2 having a thickness distribution that has a high central portion is formed on the flat SiO film S1.

In this case, since an aminosilane having one amino group is selected as the precursor and the partitioned regions Z1 to Z3 are supplied with the precursor for a supply time shorter than the saturated adsorption time, it is possible to obtain good controllability of a film thickness.

In the above, in the first embodiment, when supplying the precursor, both the supply flow rate and the supply time per unit area are made different between at least two adsorption regions among the plurality of adsorption regions of the wafer W. Further, the precursor may be supplied to some adsorption regions among of the plurality of adsorption regions of the wafer W for a supply time that is equal to or longer than the saturated adsorption time. In a corresponding adsorption region, it is possible to reliably form a thin film having the maximum film thickness. With respect to the reaction gas, it is not always necessary to make at least one of the supply flow rate and the supply time per unit area different between at least two adsorption regions among the plurality of adsorption regions of the wafer W.

### Second Embodiment

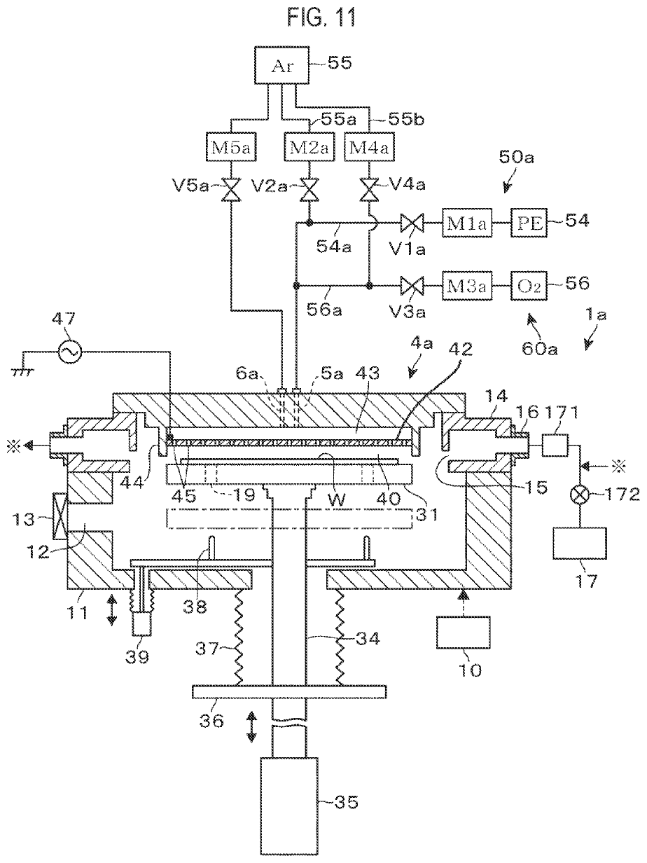

Subsequently, a second embodiment of the film forming apparatus of the present disclosure will be described with reference to FIG. 11. The difference between a film forming apparatus 1a of this embodiment and the film forming apparatus 1 of the first embodiment is that the gas diffusion space 43 of the gas ejector 4a is not partitioned. A processing gas supply path 5a for supplying a precursor and a reaction gas and a purge gas supply path 6a for supplying a purge gas are formed in the ceiling plate member 41 of the gas ejector 4a.

The processing gas supply path 5a is connected to a supply source 54 of the precursor (PE) via a precursor supply path 54a in which a valve V1a and a flow rate adjustment part M1a are installed. In addition, the processing gas supply path 5a is connected to a supply source 55 of a carrier gas (Ar) via the precursor supply path 54a and a carrier gas supply path 55a. In the carrier gas supply path 55a, a valve V2a for supplying a carrier gas and a flow rate adjustment part M2a are installed.

Further, the processing gas supply path 5a is connected to a supply source 56 of a reaction gas (O₂) via a reaction gas supply path 56a in which a valve V3a and a flow rate adjustment part M3a are installed. In addition, the processing gas supply path 5a is connected to the supply source 55 of the carrier gas via the reaction gas supply path 56a and a carrier gas supply path 55b. In the carrier gas supply path 55b, a valve V4a for supplying a carrier gas and a flow rate adjustment part M4a are installed.

In this example, the precursor supplier 50a is configured with the processing gas supply path 5a, the precursor supply path 54a, the valve V1a, the flow rate adjustment part Mla, and the supply source 54 of the precursor. Further, the reaction gas supplier 60a is configured with the processing gas supply path 5a, the reaction gas supply path 56a, the valve V3a, the flow rate adjustment part M3a, and the supply source 56 of the reaction gas. The purge gas supply path 6a is connected to the supply source 55 of the Ar gas via the valve V5a and the mass flow controller M5a. The operation of each valve and each flow rate adjustment part is controlled by the controller 10. Other configurations are the same as those of the film forming apparatus 1 of the first embodiment, the same components are denoted by the same reference numerals, and a description thereof will be omitted.

(Film Forming Method Performed in Film Forming Apparatus 1a)

Subsequently, an exemplary film forming method performed in the film forming apparatus 1a will be described. The film forming method of this embodiment controls, for example, the characteristics of a film thickness in the thickness direction. As in the first embodiment, a wafer W is delivered to the placement part 31 in the processing container 11, and a film forming cycle including supply of a precursor, purging, supply of O₂ gas, generation of a reaction product by plasmarizing the O₂ gas, and purging is repeatedly performed.

In some of the cycles carried out multiple times using an aminosilane having one amino group as a precursor, the precursor supply time allocated in one cycle is set to be shorter than the saturated adsorption time. Then, for example, after performing a preset number of cycles, in the step of supplying the precursor, the supply flow rate of the precursor is changed, and the above-mentioned film forming cycle is repeated.

As a result, since the adsorbed amount of the precursor per cycle changes before and after the change in the supply flow rate of the precursor, it is possible to form a SiO film, the characteristics (e.g., film density) of which change in the thickness direction of the thin film. In this example as well, an aminosilane having one amino group is selected as the precursor, and the precursor supply time allocated in one cycle is set to be shorter than the saturated adsorption time. Therefore, it is possible to enhance the controllability of the characteristic distribution of the thin film in the thickness direction.

### Third Embodiment

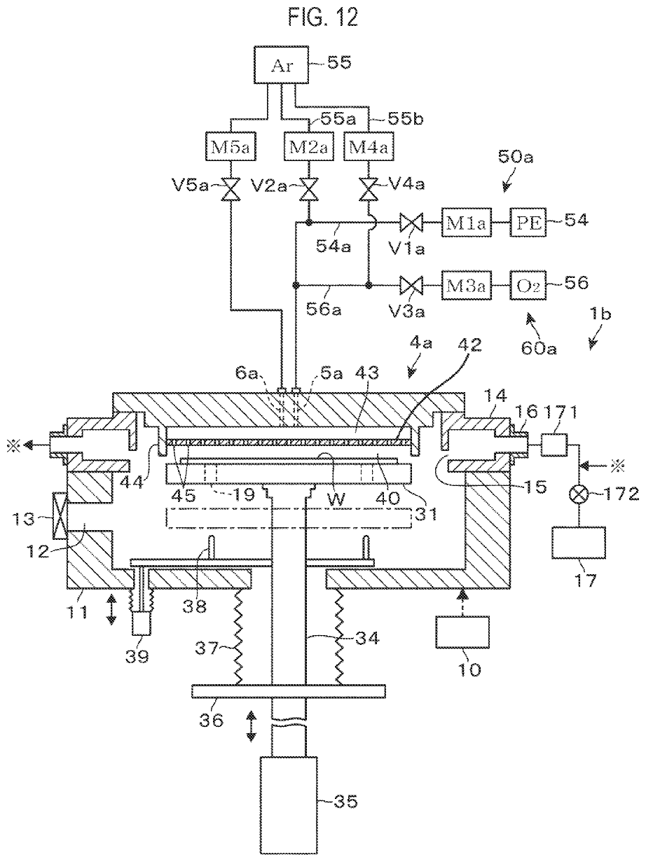

The present disclosure is also applicable to a film forming apparatus that performs thermal ALD in which a precursor and a reaction gas are reacted by thermal energy when forming a thin film on a substrate by repeating a cycle of alternately supplying the precursor and the reaction gas multiple times. A film forming apparatus 1b of this embodiment is illustrated in FIG. 12. The film forming apparatus 1b of this embodiment is different from the film forming apparatus 1a of the second embodiment in that a plasma generator for plasmarizing the reaction gas is not provided. Therefore, no high-frequency power supply is connected to the shower plate 42, and no electrode plate is installed on the placement part 31. Other configurations are the same as those of the film forming apparatus 1a of the second embodiment, the same components are denoted by the same reference numerals, and a description thereof will be omitted.

(Film Forming Method Performed in Film Forming Apparatus 1b)

In this film forming apparatus 1b, a wafer W is constantly heated to a temperature at which the precursor and the reaction gas react with each other by a heating mechanism (not illustrated) installed in the placement part 31. Then, a film forming method, which is the same as that in the film forming apparatus 1a of the second embodiment except that the wafer W is heated to perform ALD instead of generating plasma, is performed. O₃ gas) may be used as the reaction gas such that the precursor and the O₃ gas) react by thermal energy. Therefore, a film forming cycle including supplying the precursor, purging, generating a reaction product using thermal energy by supplying a reaction gas, and purging is repeated on the wafer W, which has been delivered to the placement part 31 within the processing container 11 and heated, so as to form a thin film having a target film thickness.

In this example as well, an aminosilane having one amino group is selected as the precursor, and the precursor supply time allocated in one cycle is set to be shorter than the saturated adsorption time. Therefore, it is possible to enhance the controllability of the film thickness. In addition, as in the second embodiment, it is possible to form a thin film having different characteristics in the thickness direction thereof.

In the above, in the film forming apparatus 1b, partitioned regions may be formed in the gas ejector 4 as in the first embodiment, and at least one of the supply flow rate and the supply time of the precursor per unit area may be made different between at least two partitioned regions. In this case, it is possible to form a thin film having a desired film thickness distribution by enhancing the controllability of the film thickness in the radial direction of a wafer through ALD using thermal energy.

In the present disclosure, a film forming object is not limited to a silicon substrate, and the method of the present disclosure may be applied to, for example, a film forming process for forming an SiNO film on an SiNH film. In this case, a precursor made of an aminosilane having one amino group is used as the precursor, and an oxidation gas such as O₂ gas is used as the reaction gas. Then, the precursor is adsorbed on the SiNH film, and the precursor is oxidized by plasma-activated oxygen obtained by plasmarizing the O₂ gas, thereby forming an SiNO film.

The present disclosure is also applicable to the case where a SiN film is formed on a silicon substrate by ALD using a precursor composed of an aminosilane having one amino group as the precursor and ammonia (NH₃) gas as the reaction gas. A silane having one halogen group may be used as the precursor, and the supply time of the precursor in the step of supplying the precursor to the substrate may be set to be shorter than the saturated adsorption time.

It should be understood that the embodiments disclosed herein are illustrative and are not limiting in all aspects. The above-described embodiments may be omitted, replaced, or modified in various forms without departing from the scope and spirit of the appended claims.

(Evaluation Test)

Hereinafter, an evaluation test performed in connection with the present disclosure is described. In the film forming apparatus 1a including a gas ejector 4a illustrated in FIG. 11, a SiO film was formed on a wafer W through the above-mentioned ALD process using an aminosilane to be described later as the precursor and O₂ gas as the reaction gas. The film formation rate (GPC: Å/cycle) of a SiO film was calculated when the supply flow rate of the precursor was constant and the supply time per cycle was changed. As the film forming conditions, the pressure was 2 Torr and the temperature of the wafer W was 100 degrees C.

Similarly, DIPAS (Chemical Formula 1) was used as Example (Ex1), BDEAS (Chemical Formula 2) was used as Comparative Example 1 (Com1), and 3DMAS (Chemical Formula 3) was used as Comparative Example 2 (Com2). All of Example and Comparative Examples 1 and 2 use aminosilanes, DIPAS has one amino group, Comparative Example 1 has two amino groups, and Comparative Example 2 has three amino groups.

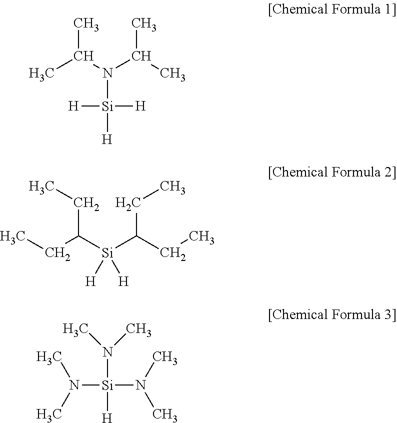

The results of film formation are shown in FIG. 13. In FIG. 13, the horizontal axis represents a supply time Ts in one cycle, the vertical axis GPC represents a film formation rate (Å/cycle), and the data are shown as Ex1 in Example, Com1 in Comparative Example 1, and Com2 in Comparative Example 2, respectively.

As described above, it was found that the shape of the supply time-deposition rate curve indicating an increase in film formation rate with respect to an increase in supply time differed substantially depending on the type of the precursor. Further, it was confirmed that the curve of Example (Ex1) had the steepest shape change and a large change in film formation rate with respect to the change in supply time. From this, it is understood that by selecting an aminosilane having one amino group as the precursor as in Example, the film thickness controllability is higher than that in the case where an aminosilane having multiple amino groups is used.

According to each curve in FIG. 13, in Example Ex1, the increase in GPC per unit time in the period during which the supply time Ts of the precursor is 0.8 to 1.2 seconds (hereinafter, referred to as a “GPC increase rate”) is about 0.09 Å/sec. In contrast, in Comparative Example 1 (Com1), the GPC increase rate in the period during which the supply time Ts is 0.8 to 1.2 seconds is about 0.03 Å/sec. In Comparative Example 2 (Com2), the GPC increase rate is about 0.04 Å/sec in the period in which the supply time Ts is 0.8 to 1.2 seconds. As described above, Comparative Examples (Com1 and Com2) are in a slightly increased state in which the increase in GPC with respect to the increase in dose amount is less than or equal to half that of Example (Ex1). From these data in FIG. 13, the time during which the amount of increase in the film formation rate when the supply time is increased by a unit time is 0.05 Å/sec or less may be regarded as being “shorter than the time required for the adsorbed amount of the precursor on the substrate to reach saturation (saturated adsorption time).”

### EXPLANATION OF REFERENCE NUMERALS

W: wafer, 1: film forming apparatus, 10: controller, 11: processing container, 31: placement part, 4: gas ejector, 42: shower plate, 50: precursor supplier, 60: reaction gas supplier

1. A method for forming a thin film on a substrate using atomic layer deposition, the method comprising:
a step of supplying a precursor, which is an aminosilane having one amino group, to the substrate,
wherein a supply time of the precursor in the step is shorter than a time required for an adsorbed amount of the precursor on the substrate to reach saturation.

2. The method of claim 1, wherein, in the step, the precursor is supplied such that at least one of a supply flow rate and a supply time of the precursor per unit area is different between at least two of a plurality of adsorption regions obtained by dividing the substrate concentrically in a radial direction.

3. The method of claim 2, wherein the substrate contains silicon terminated with a hydroxy group on a surface on which the precursor is adsorbed.

4. The method of claim 3, wherein the atomic layer deposition includes a step of supplying an oxidation gas that oxidizes the precursor adsorbed on the substrate after the step of supplying the precursor.

5. The method of claim 4, wherein the oxidation gas includes an oxygen gas activated by plasma or an ozone gas.

6. An apparatus for forming a thin film on a substrate using atomic layer deposition, the apparatus comprising:
a processing container including a placement part configured to place the substrate in the processing container;
a gas ejector including a shower plate in which a plurality of gas ejection holes is formed to face the placement part;
a precursor supplier configured to supply a precursor, which is an aminosilane having one amino group, to the gas ejector;
a reaction gas supplier configured to supply a reaction gas to the gas ejector; and
a controller configured to output a control signal that controls an ejection time of the precursor from the gas ejector to be shorter than a time required for an adsorbed amount of the precursor on the substrate to reach saturation.

7. The apparatus of claim 6, wherein a plurality of partitioned regions is formed in the gas ejector by concentrically partitioning a region in which the plurality of gas ejection holes is arranged into multiple regions corresponding to a radial direction of the substrate, the plurality of partitioned regions being configured to eject a gas independently of each other, and
the controller is configured to output a control signal that controls at least one of an ejection flow rate and the ejection time of the precursor per unit area to be different between at least two of the plurality of partitioned regions.

8. The apparatus of claim 7, further comprising:
a plasma generator configured to plasmarize the reaction gas,
wherein the controller outputs a control signal that causes the reaction gas to be plasmarized by the plasma generator when the reaction gas is ejected from the gas ejector.

9. The method of claim 1, wherein the substrate contains silicon terminated with a hydroxy group on a surface on which the precursor is adsorbed.

10. The apparatus of claim 6, further comprising:
a plasma generator configured to plasmarize the reaction gas,
wherein the controller outputs a control signal that causes the reaction gas to be plasmarized by the plasma generator when the reaction gas is ejected from the gas ejector.
